(19) United States
(12) Patent Application Publication
(10) Pub. No.: US 2026/0077998 A1
(43) Pub. Date: Mar. 19, 2026

(54) Zero Power Micro-Chemomechanical Hydrogen Sensor

(71) Applicant: Zepsor Technologies, Inc., Burlington, MA (US)

(72) Inventors: Zhenyun QIAN, Lexington, MA (US); Nabid HOSSAIN, Arlington, MA (US)

(21) Appl. No.: 19/330,620

(22) Filed: Sep. 16, 2025

Related U.S. Application Data
(60) Provisional application No. 63/694,990, filed on Sep. 16, 2024.

(51) Int. Cl. B81B 3/00; B81C 1/00

(52) U.S. Cl. CPC B81B 3/0086; B81C 1/00698; B81B 2201/01; B81B 2201/0214; B81B 2201/032; B81B 2203/0109; B81B 2203/0118; B81B 2203/04; B81C 2201/0109; B81C 2201/013; B81C 2201/016; B81C 2201/0176

(57) ABSTRACT

A micromechanical hydrogen sensor switch creates a conducting channel between two electrical contacts in response to atmospheric H₂ at or above a selected threshold. The switch uses 100 nW or less in standby mode, three orders of magnitude less than existing hydrogen sensors. The sensor converts mechanical stress caused by hydrogen absorption by palladium into movement of a cantilever structure. The switch provides automatic temperature and stress compensation, separate gates for providing bias to regulate H₂ sensitivity, a heater-based reset mechanism, low contact adhesion, and reliable platinum-to-platinum metal contacts. The sensor detects hydrogen concentrations as low as 10 parts per million (ppm) in the atmosphere.

### CROSS REFERENCE TO RELATED APPLICATIONS

This application claims the priority of U.S. Provisional Application No. 63/694,990 filed 16 Sep. 2024 and entitled “Zero Power Micro-mechanical Switch-based Hydrogen Sensor”, the whole of which is hereby incorporated by reference.

### BACKGROUND

Clean hydrogen production is anticipated to grow by several hundred megatons per annum as world governments implement policies aimed at limiting global warming to 1.5° C. in accordance with the Paris Agreement decarbonization goals. One of the areas of interest relates to the development of safe storage infrastructure, including robust leak-detection technology. Despite these initiatives, the market is currently unable to supply an affordable leak-detection solution that can detect small hydrogen leaks over a large area and requires minimal maintenance over a multi-year timeframe. Hydrogen sensors are essential for ensuring safety and operational efficiency in the expanding hydrogen economy. Current technologies include electrochemical, catalytic combustion, and solid-state sensors with wide ranges and sensitivities. Despite their wide ranges and sensitivities, current H₂ sensors are generally power-hungry, large, and expensive, presenting significant challenges for widespread deployment in the growing hydrogen infrastructure.

Commercially available sensors consume power continuously to monitor the environment even when there is no relevant data to be detected. This is a particularly critical limitation where a large number of sensors are deployed to detect infrequent but time-critical events. In such networks, the power consumed by the sensor and the electronics, waiting for infrequent events, significantly reduces the operational lifetimes (to months or less). This leads to the need for frequent battery replacements, which dramatically increases the maintenance cost and prevents the flexible placement of the sensors. While electrochemical, infrared spectroscopic, and metal oxide semiconductor gas sensor technologies have been extensively used in safety, quality control, energy, and geologic process monitoring applications, the relatively high power consumption of state-of-the-art gas sensors limits their battery life and increases the maintenance cost of sensor networks deployed in remote or hazardous locations. For example, commercially available electrochemical hydrogen gas sensors consume about 100 μW or more continuously in standby mode. Their lifetime is limited to a few weeks to a few months when deployed in regions where solar energy harvesting is not available or feasible. The use of big battery packs and/or solar panels can only marginally mitigate the problem, if sunlight is available, but it increases the cost and size of the sensor nodes. The constant power consumption in standby is attributed to the use of active electronics for signal conditioning and processing in state-of-the-art gas sensors, which accounts for the great majority of total consumed energy. Thus, there is a need for hydrogen sensors that consume minimal energy in standby mode and have a small size.

### SUMMARY

The present invention provides a microelectromechanical systems (MEMS) hydrogen sensor that selectively harvests the energy contained in atmospheric H₂ and uses it to mechanically create a conducting channel between two electrical contacts when the strength of the signal is above a predetermined threshold, without the need for any additional power source. Otherwise, the switch remains open on standby, separating the battery from any load electronics, hence enabling zero power consumption in standby mode. The working principle of the device is based on hydrogen absorption by palladium, a reversible process that changes stress in palladium, which can be utilized to close the MEMS switch. Even when enhanced with a voltage regulator to adjust the H₂ detection threshold, the present sensor operates with a standby power consumption three orders of magnitude lower than state of the art H₂ sensors.

The event-driven sensing capability of the present sensor lies in the integration of the hydrogen absorption by palladium into a temperature-compensated MEMS switch. Further design elements such as separated gates for voltage bias, automatic temperature and stress compensation, heater-based reset mechanism, low contact adhesion, and reliable platinum-to-platinum metal contacts, are integrated into embodiments of the device. The zero-power hydrogen sensor integrates sensing, signal processing, and comparator functionalities into a single microsystem. This novel digitized gas sensor is capable of detecting hydrogen concentrations as low as 10 parts per million (ppm) in the atmosphere while consuming no more than 100 nW in standby (used by a voltage regulator supporting the sensor) and maintaining a low false alarm rate.

In the sensor architecture, a suspended MEMS switch is triggered by above-threshold H₂ concentrations in the air due to reversible absorption of H₂ in the palladium layer of an aluminum/palladium bilayer structure, leading to bending of the structure. The switch is a three-terminal switch with a platinum-coated upper metal contact tip (acting as a drain) and a lower contact base (acting as a source). A separate electrode placed underneath the contact tip, but retracted from the contact base (source) serves as a gate by applying a bias voltage that controls the H₂ detection threshold and sensitivity of the switch. The actuation mechanism of the PFMS is based on the combination of hydrogen-induced stress change in Pd and the principle of electrostatic pull-in behavior of a cantilever-supported parallel plate capacitor. With absorption of H₂, the inner beams of the pair of folded beams deflect downward because of the compressive stress developed from Pd hydriding. By applying a voltage bias between the contact tip and the gate below the pull-in voltage, the switch can be triggered at a pre-determined concentration of H₂. Such a threshold is a function of inherent device sensitivity resulting from displacement dependence on H₂ concentration, beam stiffness, contact area, and contact gap, and it can be effectively changed even after fabrication by changing the bias voltage through the voltage regulator.

Once triggered by an above threshold H₂ concentration, the upper contact tip is pulled toward the bottom contact base and therefore connects the system battery to the load electronics, such as by direct connection to a capacitive load or through a load switch for high-power delivery. The switch is designed to latch upon triggering. After the completion of the program of the wireless sensor node, the switch can be reset to open by simply removing the voltage bias from the gate. If the ambient H₂ level drops below the target threshold (10 ppm), the switch will remain open, disconnecting the system battery from the output load, resulting in near-zero standby power consumption.

Unlike existing H₂ sensors, the present sensor exploits the high sensitivity and rapid response of a uniquely designed MEMS switch, enabling the detection of H₂ concentrations as low as 10 ppm in the air while consuming nearly zero power (<100 nW).

The invention can also be summarized with the following listing of features.
1. A hydrogen (H₂) sensing microelectromechanical system (MEMS) device, comprising
   a hydrogen sensitive sensor portion, the sensor portion comprising
      an insulating substrate;
      a pair of U-shaped structures, each structure comprising an inner beam, an outer beam in parallel alignment with the inner beam, and a curved connector beam that connects the inner and outer beams;
         wherein the inner beams comprise a lower conductive layer and an upper hydrogen absorbing layer disposed on the conductive layer;
         wherein the outer beams comprise a lower conductive layer, a middle hydrogen absorbing layer disposed on the conductive layer, and an upper insulating layer disposed on the hydrogen absorbing layer, and wherein the conductive layer of the outer beams is connected to a pair of first contact pads disposed on the substrate;
         wherein the curved connector beams comprise only a conductive layer, and wherein the conductive layer of the curved connector beams is connected at one end to the connective layer of the inner beams and at another end to the conductive layer of the outer beams;
      a bridge connecting the inner beams of the pair of U-shaped structures, the bridge comprising a lower metal contact layer and an upper conductive layer; and
      a contact tip connected to the bridge, the contact tip comprising a lower metal contact layer, a middle conductive layer, and an upper hydrogen absorbing layer;
   wherein the pair of U-shaped structures, the bridge, and the contact tip form a structural unit that is suspended above the substrate and anchored to the substrate at ends of the outer beams opposite the curved connector beams, and wherein said conductive layers provide a continuous conductive pathway from said first contact pads to said contact tip;
   a second (source) contact pad disposed on the substrate beneath a forward portion of the contact tip and connected via a conductive pathway to a first (source) circuit contact; and
   a third (bias) contact pad disposed on the substrate beneath a rear portion of the contact tip and connected via a conductive pathway to a third (bias) circuit contact;
   wherein binding of H₂ to said hydrogen absorbing layer produces a conformational change in said inner beams resulting in movement of the contact tip towards the second and third contact pads, and wherein H₂ present above a detection threshold provides electrical contact between the first contact pads and the second and third contact pads.
2. The MEMS device of feature 1, wherein the hydrogen absorbing layer comprises one or more of Pd, Pd—Au alloy, carbon nanotubes (CNTs), Mg, and Pd nanostructures, wherein said Pd nanostructures optionally further comprise one or more of Pt, SnO₂, WO₃, ZnO, or graphene.
3. The MEMS device of feature 1 or feature 2, wherein the insulating substrate comprises high resistivity Si, or doped Si coated with a passivating layer.
4. The MEMS device of any of the previous features, wherein the conductive metal layer comprises aluminum, gold, titanium, platinum, or any alloy of the foregoing.
5. The MEMS device of any of the previous features, wherein the upper insulating layer of the outer beams comprises a material selected from the group consisting of Al₂O₃, Si₃N₄, TiN, HfO₂, ZrO₂, TiO₂, SiO₂, and combinations thereof.
6. The MEMS device of feature 5, wherein the upper insulating layer of the outer beams is fabricated by atomic layer deposition.
7. The MEMS device of any of the previous features, further comprising a heater for resetting the device after a hydrogen-induced triggering event.
8. The MEMS device of feature 7, wherein the heater comprises a serpentine conductive metal layer disposed on any of the contact tip, bridge, or substrate adjacent to the source or gate contact pads.
9. The MEMS device of any of the previous features, wherein the device has a power consumption of 100 nW or less in standby mode, when used with a voltage regulator to maintain a desired voltage bias.
10. The MEMS device of any of the previous features, wherein the device further comprises one or more of a battery, a voltage regulator, a wireless sensor node, a processor, a memory, a status indicator or display, a visual or audible alarm, a package housing, a control for regulating the bias voltage, or a load switch for controlling another device.
11. The MEMS device of any of the previous features, wherein the device is part of a network of hydrogen sensor devices.
12. A system for detecting hydrogen gas, the system comprising one or more MEMS devices of any of the previous features and a reader device that receives a signal from the one or more devices upon detecting hydrogen gas at or above a selected threshold concentration.
13. A method of detecting hydrogen gas in an environment, the method comprising deploying one or more MEMS devices of any of features 1-11 in said environment and monitoring the devices for a signal indicating detection of hydrogen gas at or above a selected threshold concentration.
14. A method of fabricating the MEMS device of any of features 1-11, the method comprising
   (a) depositing one or more metal contact pads on a surface of an insulating substrate;
   (b) depositing a passivating oxide layer on the surface and the metal contact pads;
   (c) etching the oxide layer to provide a pattern of vias for deposition of a conductive metal;
   (d) depositing the conductive metal in the vias to form the conductive metal layer of the cantilever structure of the device;
   (e) depositing a hydrogen absorbing material on selected areas of the conductive metal layer to form the inner and outer beams of the cantilever structure of the device;
   (f) depositing an insulating material on the hydrogen absorbing material of the outer beams of the device; and
   (g) etching the oxide layer according to a pattern, thereby forming and releasing the cantilever structure.
15. The method of feature 14, further comprising integrating the MEMS device into a circuit or connecting it to one or more of a battery, a voltage regulator, a wireless sensor node, a processor, a memory, a status indicator or display, a visual or audible alarm, a package housing, a control for regulating the bias voltage, another device, or a load switch for controlling another device.

### BRIEF DESCRIPTION OF THE DRAWINGS

FIG. 1A shows a schematic illustration of an embodiment of a zero power hydrogen sensor of the invention, including a palladium-coated folded-bimorph-beam micromechanical switch (PFMS) comprising four bimaterial beams arranged in two pairs, each pair containing an inner beam, an outer beam, and a curved connector beam, forming a U-shaped structure. The two U-shaped structures are arranged with mirror symmetry and connected by a bridge at the ends of the inner beams opposite the curved connector beams. A contact tip is attached to the bridge, and motion of the contact tip is responsible for closing and opening the switch. The two inner beams bend downward in response to H₂ present in the atmosphere surrounding the sensor due to stress induced by hydriding the Pd layer with the H₂; the downward bending causes the contact tip to also move downward and close a gap with contact pads on the substrate below, one of which serves as the source electrode. Like the contact tip, the bridge also has a metal contact layer, such as Pt, as its lower layer, so that the bridge structure in addition to the contact tip can take part in making electrical contact when the switch is activated. The outer beams do not bend in response to H₂ because their palladium layer is coated with Al₂O₃ on top. FIG. 1B shows a simulated displacement plot of the U-shaped beam structures showing downward deflection from H₂ induced stress in the palladium layer. FIG. 1C shows a close-up view of the metal contacts depicted in FIG. 1A. FIG. 1D shows a schematic diagram of a device containing the zero power hydrogen sensor of the present invention, wherein the sensor serves as a switch between a battery and a wireless node, with a voltage regulator circuit acting as a gate to control the activation threshold for the switch. FIGS. 1E-1F are schematic representations of the switching mechanism of the sensor. In FIG. 1E the H₂ concentration is below the threshold and the switch is open. In FIG. 1F, the H₂ concentration is at or above the threshold, and H₂ absorption by palladium leads to compressive stress which causes the inner beams to bend downward, closing the switch at the contact tip.

FIG. 2A shows a schematic illustration of a PFMS including a heater for resetting the switch. The heater forms the bridge and contact tip structures and contains a bottom layer of insulating material (e.g., AlN) interrupted by a serpentine metal structure (e.g., platinum) connected to a pair of reset contacts on the substrate. FIG. 2B is a close-up view of the contact area with serpentine heater beneath the insulator layer. FIG. 2C shows a top view of the heater layer with serpentine design, which can be extended to the right as needed to meet power requirements of the heater.

FIG. 3A shows a schematic illustration of a PFMS having an alternative heater design in which the heater is positioned on the substrate and surrounding, but not covering, the bridge and contact tip. FIG. 3B is a close-up view of the contact area with surrounding serpentine heater on the substrate. FIG. 3C is a top view of the heater layer with serpentine design, whose heater area can be adjusted to meet power requirements.

FIG. 4 shows a top view of a PFMS with materials in cross-section and preferred dimensions at different parts of the structure.

FIG. 5 shows cross-sectional structure and materials during steps of a nanofabrication process for of the PFMS.

FIGS. 6A-6D show predictions of a Pd-hydriding model. FIG. 6A shows hydrogen-induced compressive stress in Pd at 1-10 ppm of H₂ concentration. FIG. 6B shows simulated displacement in PFMS at 10 ppm of H₂ concentration obtained using a finite element analysis. FIG. 6C shows simulated deflection sensitivity to H₂ concentration/induced stress obtained by finite element analysis. FIG. 6D shows simulated deflection sensitivity to ambient temperature obtained by finite element analysis.

FIG. 7A shows predicted tip displacement and FIG. 7B shows required H₂ threshold at various applied biases in order to trigger electrostatic actuation. The range of voltages in the dashed region of FIG. 7B is of the detection range of 1-10 ppm.

FIG. 8 shows a comparison of tip deflection between Al/Pd-based and Au/Pd-based MEMS designs for H₂ sensing.

### DETAILED DESCRIPTION

The zero power hydrogen sensor of the invention is based on a palladium-coated folded bimorph beam micromechanical switch (PFMS). A bimorph, as used herein, refers to a cantilever structure containing two active layers. The working principle of a PFMS relies on bimorph beams that are selectively activated by H₂ absorption in a palladium layer of the bimorph at or above a specific concentration threshold in the air. The absorbed hydrogen causes the palladium layer to expand, creating stress that results in bending of the bimorph, which creates a conducting channel between a lower contact base (source) and an upper metal contact tip (drain).

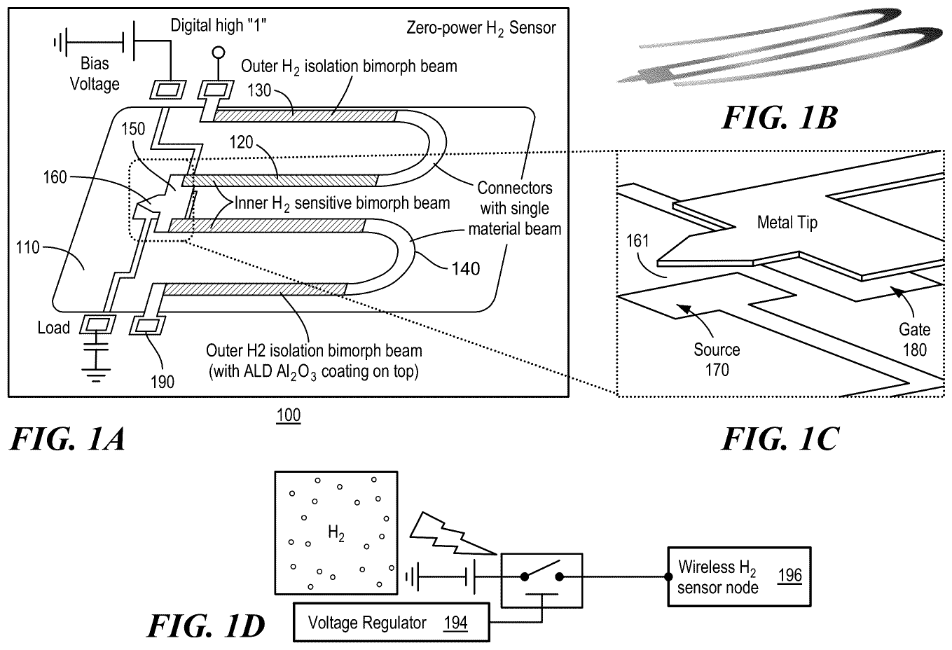

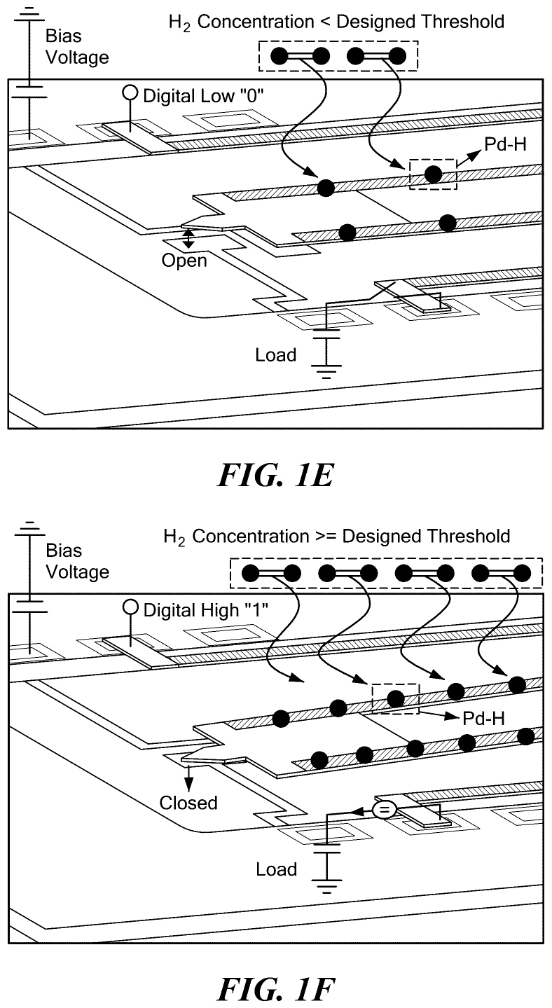

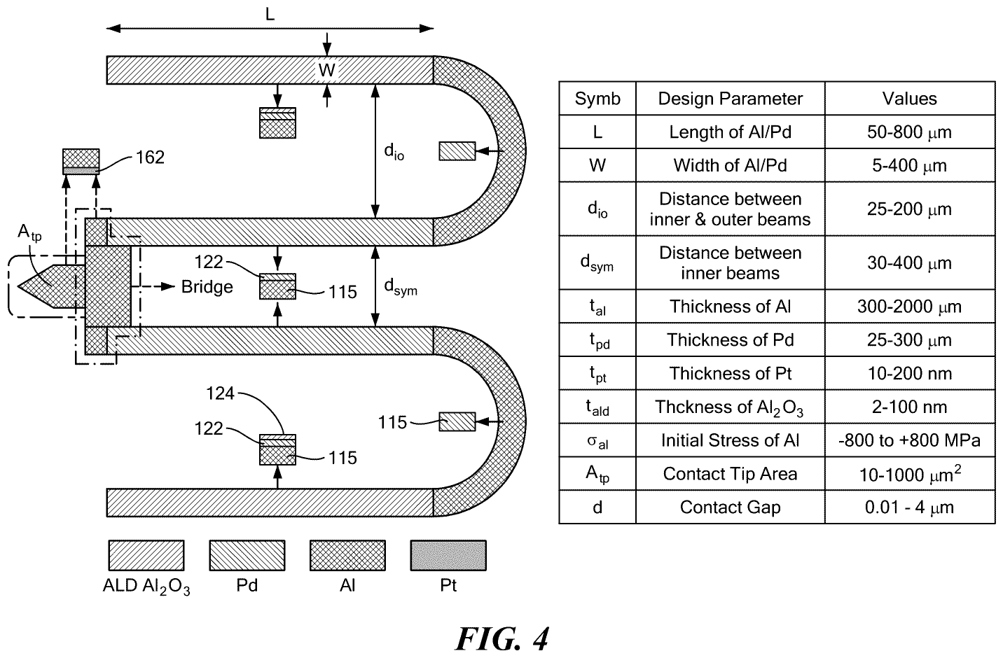

Referring now to FIG. 1A, PFMS 100 contains a symmetrical, released, folded cantilever with different material stacks in the inner and outer beams (FIGS. 1A and 4). The cantilever is suspended over insulating substrate 110. Conductive metal layer 115 forms the continuously conductive base and support layer throughout the entire cantilever structure. Inner beams 120 have an upper exposed hydrogen binding layer 122 containing Pd or another H₂ binding material for H₂ absorption and bimorph actuation. Outer beams 130 have the same hydrogen binding material layer, but in the outer beams the hydrogen binding material is completely covered with an ultrathin (preferably 2-5 nm thickness) insulating layer 124 of an insulating material, such as Al₂O₃, which is preferably deposited by atomic layer deposition (ALD) to assure even and essentially defect-free coverage. This configuration of the outer beams renders them isolated from and insensitive to H₂. The inner and outer beams on each side of the cantilever structure are joined by curved connector beam 140, which contains only the conductive metal layer without further materials deposited thereupon. Since the shape, bimorph layer structure, and most of the materials of the inner and outer beams are identical, and because of their connection by the arch-shaped connector beam, the dual beam cantilever structure serves to compensate for temperature changes and mechanical shock, such that these effects are cancelled out, resulting in no movement of the contact tip, which responds only to the presence of H₂. The connector beam also keeps the contact gap stable during fabrication and below the H₂ triggering limit over a wide range of ambient temperatures. Bridge 150 connects the inner beams, thereby joining the two U-shaped structures on either side of the cantilever. The bridge also supports contact tip 160 for actuating and biasing with the source and the gate electrodes. See FIGS. 1A and 4. In a preferred embodiment, the contact tip attached to the bridge has bottom Pt layer 162 attached, and source contact pad 170 on the substrate also consists of Pt, enabling Pt—Pt contact between the bottom source and drain electrodes during actuation (FIGS. 1E-1F). Due to the rotational displacement caused by H₂ binding to the palladium layer, the contact tip will touch the source electrode before the gate is shorted. Contact gap 161 between the metal tip and the source electrode is preferably about 2 μm, and can be fabricated using about 2 μm of SiO₂ as a sacrificial layer between the substrate and the conductive metal layer. Source 170 and gate 180 contacts (bottom electrodes) can be directly deposited onto a high-resistivity Si substrate and are electrically connected to the respective terminals. The outer beams are anchored to the substrate through aluminum pads 190 deposited on the substrate, and electrically connected to the circuit through gold pads deposited on the aluminum pads. If H₂ is absorbed into the Pd layer of inner beams, compressive stress is induced into the structure, which will deflect the cantilever downward, depending on the amount of induced internal stress. Bias voltage is supplied by voltage regulator 192 positioned between ground and the gate contact pad. Wireless node 196 is the load connected between ground and the source contact pad. The wireless node is activated by closing of the switch, and upon activation can transmit a battery driven radio frequency signal to indicate detection of H₂ at or above the detection threshold.

The actuation mechanism of the PFMS is based on the combination of hydrogen-induced stress change in Pd and the principle of electrostatic pull-in behavior of a cantilever-supported parallel plate capacitor. With the introduction of H₂ in the air in the environment of the sensor, the inner beams of the pair of folded beams deflect downward because of the induced compressive stress developed from Pd hydriding kinetics. Applying a voltage bias between the contact tip and the gate below the pull-in voltage can trigger the switch at a certain pre-determined concentration of H₂; thus, changing this bias can change the activation threshold of the sensor. Such a threshold is a function of device sensitivity (displacement vs. H₂ concentration), beam stiffness, contact area, and contact gap, and it can be effectively changed even after fabrication by tuning the bias voltage (through the voltage regulator). Once triggered by the above threshold variation of H₂ concentration, the top contact tip gets pulled into the bottom contact base and therefore connects the system battery to the load electronics (direct connection to a capacitive load or through a load switch for high-power delivery).

The interaction between hydrogen and a hydrogen-absorbing metal like Pd is defined by a hydriding mechanism which consists of four consecutive steps: molecular adsorption, dissociative chemisorption, diffusion, and interstitial absorption. When palladium finally absorbs hydrogen, the resulting palladium hydride phase is formed with hydrogen atoms occupying the octahedral interstitial sites of the fcc Pd lattice. At full occupancy of these sites, the hydride composition approaches the ideal stoichiometry of PdH. The overall absorption process can be expressed by the equilibrium reaction:

$$P d + \frac{x}{2} {H}_{2} ↔ {PdH}_{x} + x Δ {H}_{a b}$$

where x represents the hydrogen-to-palladium atomic ratio and ΔH_{ab} is the enthalpy of absorption per H atom. This relationship captures the reversible formation of palladium hydride and provides the thermodynamic basis for Pd's utility in hydrogen storage and sensing applications. Upon H₂ absorption, the Pd film undergoes lattice expansion that generates compressive stress within the constrained layer. In a Pd/Al bimorph, this stress mismatch induces downward bending to the free end of the folded cantilever beam. The H₂-induced stress (Δσ) is directly related to the bulk H/Pd atomic ratio (n) through the following analytical relation¹

$$Δ σ = \frac{{E}_{f}}{3 ( 1 - {v}_{f} )} \frac{Δ V}{V} = \frac{{E}_{f}}{3 ( 1 - {v}_{f} )} \frac{Δ v}{{Ω}_{p d}} n ;$$

Where E_{f} and ν_{f} are the Young modulus and Poisson's ratio of the Pd film. The ratio ΔV/V and n are equal to Δv/Ω_{pd}, where Δv is the characteristic volume change per hydrogen atom, and Ω_{pd} is the mean atomic volume of a palladium atom. This ratio describes the lattice expansion due to hydrogen uptake. The bulk H/Pd atomic ratio n can be linked to the partial pressure of H₂ in air by Sievert's law in equilibrium a phase of Pd hydriding:

$$Δ {σ}_{e q} = Q {n}_{e q} = Q \frac{\sqrt{P {H}_{2}}}{{K}_{s}}$$

Where PH₂ is the partial pressure of H₂, and Kₛ is Sievert's constant. From this H₂-induced stress (Δσ), the bending curvature (K) and tip deflation (Wₜᵢₚ) can be evaluated by the following:

$$κ = {K}_{b i} Δ {σ}_{e q} ; {W}_{tip} \approx \frac{{L}^{2}}{2} κ$$

Here K_{bi} is a Timoshenko/Stoney geometry-materials factor set by layer thicknesses and moduli of the bimorph films. Thus, when a certain concentration of H₂ is present in air, the corresponding tip deflection of the PFMS can be calculated using the above theories. This phenomenon of PFMS bending due to the presence of H₂ in air is illustrated in FIGS. 1E-1F.

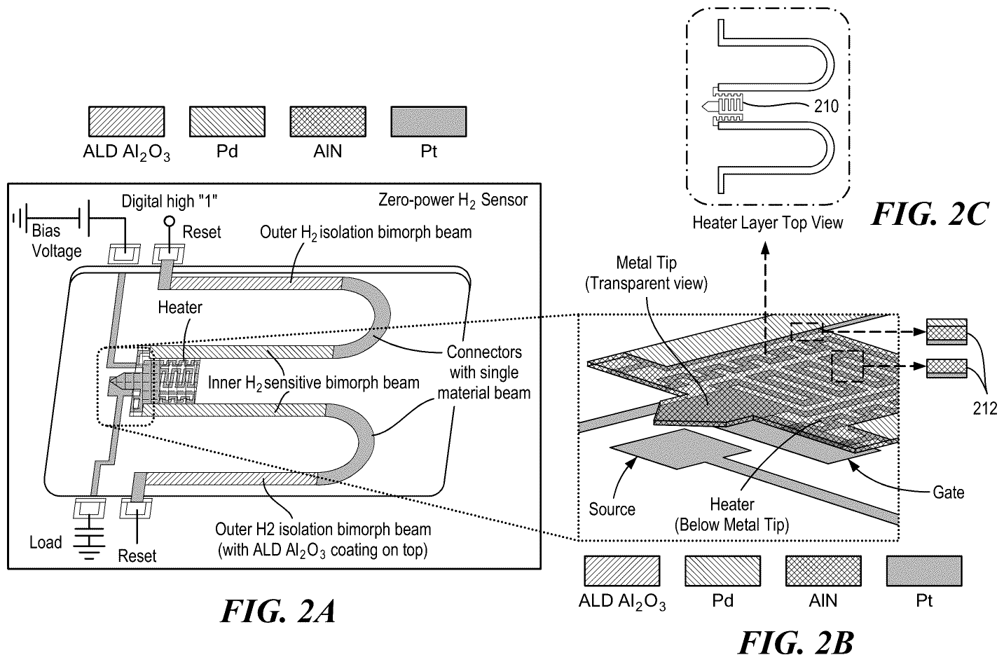

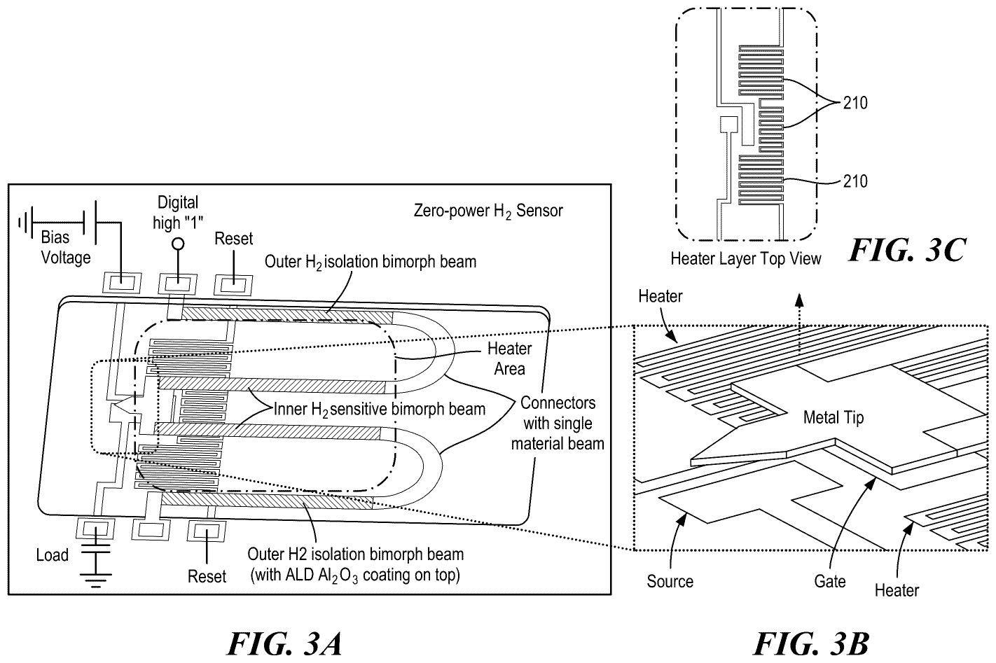

The switch is designed to latch upon triggering. After the completion of the program of the wireless sensor node, the switch can be reset to open by simply removing the voltage bias from the gate. If the ambient H₂ level drops below the target threshold (10 ppm), the switch will remain open, disconnecting the system battery from the output load, resulting in a near-zero standby power consumption. However, the adhesion between the contacts may become sufficiently strong so that the switch fails to reopen even after the hydrogen concentration falls below the target threshold. Accordingly, in addition to the base design illustrated in FIGS. 1A and 1C, two alternative switch configurations are shown in FIGS. 2A-2C and 3A-3C. These configurations operate in the same manner as the base design but further incorporate integrated heater elements that can be selectively activated to unlatch the switch if it remains closed despite the reduction of hydrogen below the threshold level. In the configuration of FIGS. 2A-2C, serpentine heater 210 is fabricated on the backside of insulating layer 212, which replaces the bottom bimorph material of the bridge and/or contact tip of the base design. In the configuration of FIGS. 3A-3C, the serpentine heater is fabricated directly on the substrate, adjacent to the electrodes configured for the source and gate.

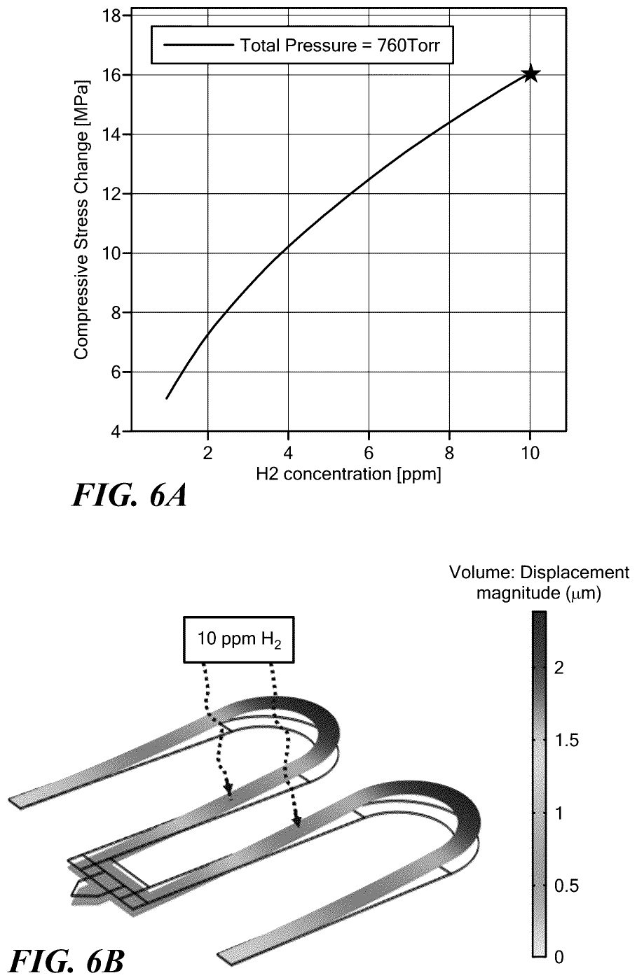

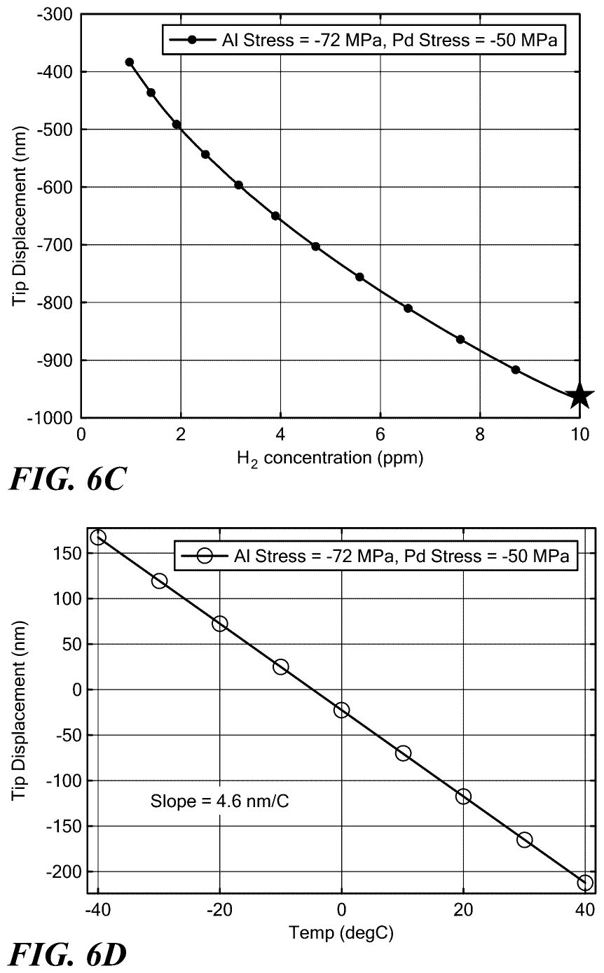

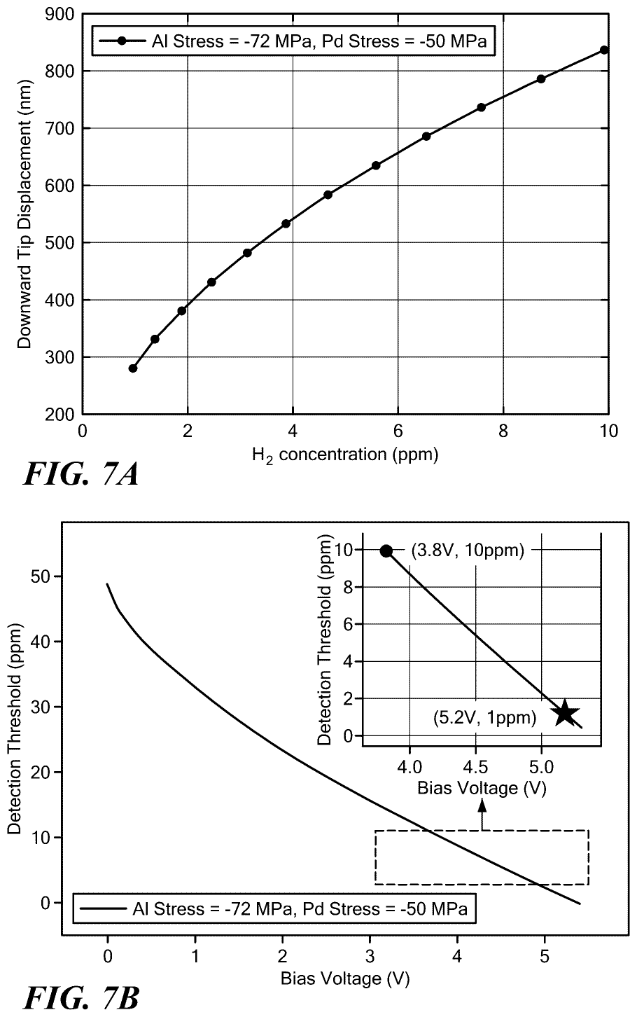

The deflection of the PFMS structure in response to H₂ is sensitive to design parameters such as lateral dimensions of structural components, film thicknesses, fabrication outcomes such as residual stress in the structure, and ambient conditions such as temperature and humidity. Finite element analysis shows that, with a compressive residual stress of 72 and 50 MPa in the Al and Pd layers, respectively, a prototype design had a maximum displacement of 2.5 μm towards the connectors of the folded beams (as illustrated in FIG. 6B, but before exposure to H₂) and negligible displacement in the tip area. Once exposed to H₂, the inner beams bend downward because of induced compressive stress via Pd—H₂ hydriding kinetics. Finite element analysis shows that 1-10 ppm of H₂ concentration in the atmospheric air induces 3-16 MPa of internal compressive stress in the Pd layer that deflects the contact tip downward by 400-980 nm (FIGS. 6A, 6C). At 10 ppm H₂ concentration, the tip deflects ^{˜}1 μm (FIG. 6B, 6C), enough to trigger the electrostatic actuation by biasing at 3.8V, which is below the pull-in voltage (5.4V) of the supporting circuitry. The minimum threshold of H₂ detection can further be decreased to 1 ppm by increasing the bias voltage close to 5.2V, as predicted by the calculation shown in FIG. 7B. Low H₂ concentrations of ^{˜}1 ppm can be obtained by optimizing the design dimensions such as the bimorph beam dimensions, materials, and film thicknesses and reducing the bias voltage requirement.

The electrostatic pull-in and threshold at a bias can be calculated using the MEMS parallel plate electrostatic pull-in theory as follows:

$$T {h}_{b} = T {h}_{0} * ( 1 - {( \frac{{V}_{b}}{{V}_{p}} )}^{2 / 3} ) ; {V}_{p} = \sqrt{\frac{8 k {g}_{{0}^{3}}}{27 ε A}}$$

Here, Th₀ is the concentration of H₂ required to close the initial gap (g₀) with 0 V bias applied, and Th_{b} is the concentration of H₂ required when a bias voltage (V_{b}) is applied. Vₚ is the electrostatic pull-in voltage of the MEMS device, which is defined by the above V, equation, where k, ε, A are the device stiffness, the permittivity of air, and the overlapping area between the metal tip and the gate.

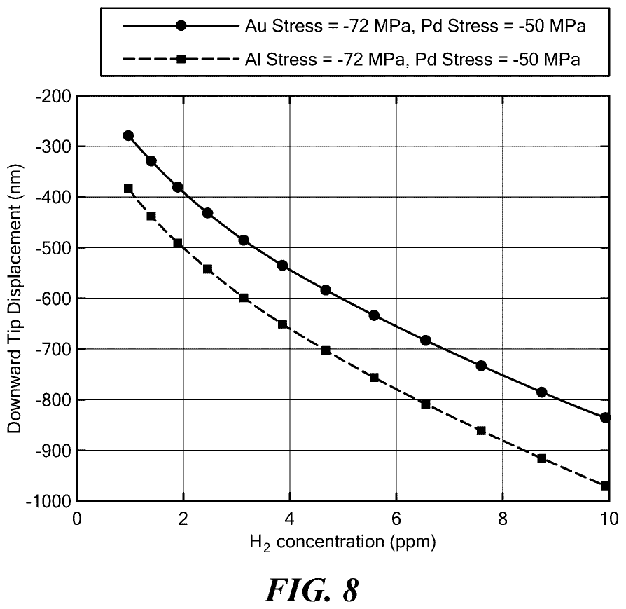

The PFMS is immune to ambient temperature fluctuations in a range from about −40 to +40° C. Temperature variation finite element analysis results (see FIG. 6D) predict a maximum downward tip displacement of 200 nm due to such temperature variations, which cannot trigger the switch. The temperature sensitivity of a prototype design was 4.6 nm/° C., which can be lowered further by design optimization. There can be a strong galvanic couple between Al and Pd when exposed to an ambient environment, which can corrode Al. To mitigate this possible failure, Al and Pd can be isolated from each other by adding a thin layer of alumina (Al₂O₃) on top of the Al layer before the deposition of Pd. Alumina will not only electrically insulate the Al/Pd interface but also protect exposed aluminum from corrosion. Alternatively, aluminum can be replaced with gold, a more noble and corrosion-resistant metal. The Au/Pd-based PFMS design showed similar bimorph deflection and H₂ detection threshold without a significant drop in device sensitivity, as shown in FIG. 8.

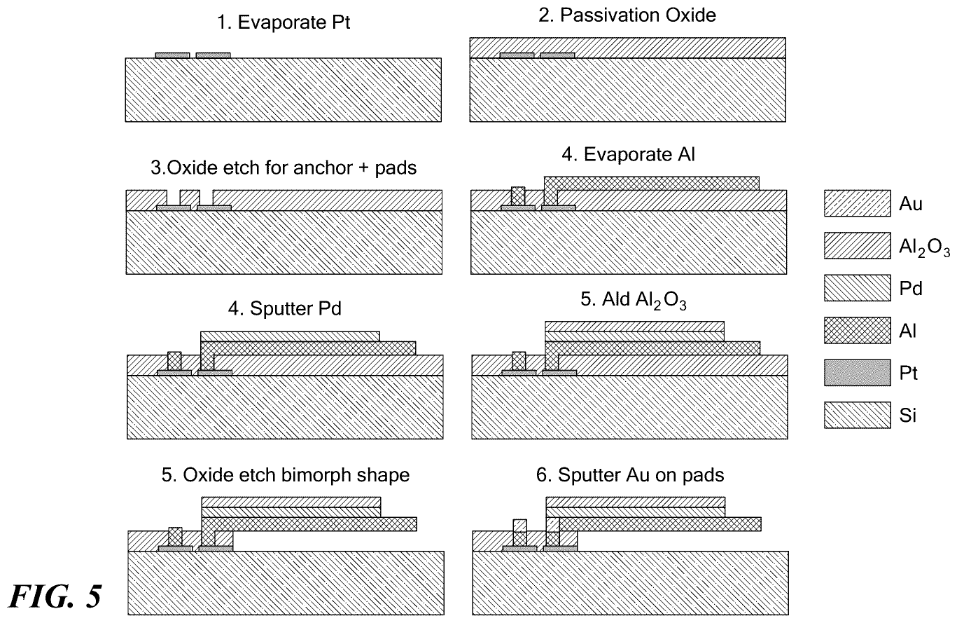

Fabrication of the PFMS can follow a process of nanofabrication as illustrated in FIG. 5. First, bottom electrodes are directly deposited by evaporation or sputtering deposition (Pt preferred) onto an insulating substrate (high-resistivity silicon (Si) preferred, or a doped Si substrate with passivation). Then, a thin layer of a sacrificial material (silicon dioxide (SiO₂) preferred) of thickness equal to the desired contact gap is grown over the substrate surface, such as by chemical vapor deposition (CVD); this sacrificial layer defines the gap between the substrate and the conductive layer (e.g., aluminum (Al)) to be deposited next. The sacrificial layer is etched at anchor sites, and Al is deposited to form vias for electrode-pad electrical connection and outer beam anchors, as well as to form the conductive base layer of the cantilever beams, bridge, and contact tip. A thin layer of palladium (Pd) is then deposited on top of the Al layer on the inner and outer beams, and then an ultra-thin layer of insulating material such as aluminum oxide (Al₂O₃) is deposited by atomic layer deposition on top of the Pd of the outer beams to isolate the outer beams from H₂ absorption. After that, the rest of the SiO₂ will be etched to form the bimorph shape. Finally, gold (Au) can be sputtered onto vias to form conductive pads, and the device will be released from the substrate through isotropic SiO₂ etch. Preferred and alternative materials for each of the layers are shown in Table 1.

TABLE 1
List of materials.

| Layer in | Preferred | |
|---|---|---|
| Material Stack | Material | Alternative Materials |
| Bottom of | Al | Au, Ti, AlN (heater, where no metal) |
| bimaterial layer | | |
| Insulating layer | Al₂O₃ | SiN₄, TiN, HfO₂, ZrO₂, TiO₂, SiO₂ |
| on outer beams | | |
| Top of | Pd | Pd—Au alloys; Pd nanostructures; Pt, |
| bimaterial layer | | SnO₂, WO₃, ZnO, or graphene |
| | | individually or optionally combined |
| | | with Pd nanoparticles; carbon |
| | | nanotubes (CNTs); Mg |
| Insulation Layer | AlN | SiO₂, SiN₄ |
| on heater | | |

As used herein, “consisting essentially of” allows the inclusion of materials or steps that do not materially affect the basic and novel characteristics of the claim. Any recitation herein of the term “comprising”, particularly in a listing of components of a composition or elements of a device, constitutes inclusion of alternative embodiments in which “comprising” is replaced with “consisting essentially of” or “consisting of”.

While the present invention has been described in conjunction with certain preferred embodiments, one of ordinary skill, after reading the foregoing specification, will be able to effect various changes, substitutions of equivalents, and other alterations to the compositions and methods set forth herein.

### REFERENCE

[1] Delmelle, R. and Proost, J., 2011. An in situ study of the hydriding kinetics of Pd thin films. Physical Chemistry Chemical Physics, 13(23), pp. 11412-11421.

What is claimed is:

1. A hydrogen (H₂) sensing microelectromechanical system (MEMS) device, comprising
a hydrogen sensitive sensor portion, the sensor portion comprising
an insulating substrate;
a pair of U-shaped structures, each structure comprising an inner beam, an outer beam in parallel alignment with the inner beam, and a curved connector beam that connects the inner and outer beams;
wherein the inner beams comprise a lower conductive layer and an upper hydrogen absorbing layer disposed on the conductive layer;
wherein the outer beams comprise a lower conductive layer, a middle hydrogen absorbing layer disposed on the conductive layer, and an upper insulating layer disposed on the hydrogen absorbing layer, and wherein the conductive layer of the outer beams is connected to a pair of first contact pads disposed on the substrate;
wherein the curved connector beams comprise only a conductive layer, and wherein the conductive layer of the curved connector beams is connected at one end to the connective layer of the inner beams and at another end to the conductive layer of the outer beams;
a bridge connecting the inner beams of the pair of U-shaped structures, the bridge comprising a lower metal contact layer and an upper conductive layer; and
a contact tip connected to the bridge, the contact tip comprising a lower metal contact layer, a middle conductive layer, and an upper hydrogen absorbing layer;
wherein the pair of U-shaped structures, the bridge, and the contact tip form a structural unit that is suspended above the substrate and anchored to the substrate at ends of the outer beams opposite the curved connector beams, and wherein said conductive layers provide a continuous conductive pathway from said first contact pads to said contact tip;
a second (source) contact pad disposed on the substrate beneath a forward portion of the contact tip and connected via a conductive pathway to a first (source) circuit contact; and
a third (bias) contact pad disposed on the substrate beneath a rear portion of the contact tip and connected via a conductive pathway to a third (bias) circuit contact;
wherein binding of H₂ to said hydrogen absorbing layer produces a conformational change in said inner beams resulting in movement of the contact tip towards the second and third contact pads, and wherein H₂ present above a detection threshold provides electrical contact between the first contact pads and the second and third contact pads.

2. The MEMS device of claim 1, wherein the hydrogen absorbing layer comprises one or more of Pd, Pd—Au alloy, carbon nanotubes (CNTs), Mg, and Pd nanostructures, wherein said Pd nanostructures optionally further comprise one or more of Pt, SnO₂, WO₃, ZnO, or graphene.

3. The MEMS device of claim 1, wherein the insulating substrate comprises high resistivity Si, or doped Si coated with a passivating layer.

4. The MEMS device of claim 1, wherein the conductive metal layer comprises aluminum, gold, titanium, platinum, or any alloy of the foregoing.

5. The MEMS device of claim 1, wherein the upper insulating layer of the outer beams comprises a material selected from the group consisting of Al₂O₃, Si₃N₄, TiN, HfO₂, ZrO₂, TiO₂, SiO₂, and combinations thereof.

6. The MEMS device of claim 5, wherein the upper insulating layer of the outer beams is fabricated by atomic layer deposition.

7. The MEMS device of claim 1, further comprising a heater for resetting the device after a hydrogen-induced triggering event.

8. The MEMS device of claim 7, wherein the heater comprises a serpentine conductive metal layer disposed on any of the contact tip, bridge, or substrate adjacent to the source or gate contact pads.

9. The MEMS device of claim 1, wherein the device has a power consumption of 100 nW or less in standby mode, when used with a voltage regulator to maintain a desired voltage bias.

10. The MEMS device of claim 1, wherein the device further comprises one or more of a battery, a voltage regulator, a wireless sensor node, a processor, a memory, a status indicator or display, a visual or audible alarm, a package housing, a control for regulating the bias voltage, or a load switch for controlling another device.

11. The MEMS device of claim 1, wherein the device is part of a network of hydrogen sensor devices.

12. A system for detecting hydrogen gas, the system comprising one or more MEMS devices of claim 1 and a reader device that receives a signal from the one or more devices upon detecting hydrogen gas at or above a selected threshold concentration.

13. A method of detecting hydrogen gas in an environment, the method comprising deploying one or more MEMS devices of claim 1 in said environment and monitoring the devices for a signal indicating detection of hydrogen gas at or above a selected threshold concentration.

14. A method of fabricating the MEMS device of claim 1, the method comprising
(a) depositing one or more metal contact pads on a surface of an insulating substrate;
(b) depositing a passivating oxide layer on the surface and the metal contact pads;
(c) etching the oxide layer to provide a pattern of vias for deposition of a conductive metal;
(d) depositing the conductive metal in the vias to form the conductive metal layer of the cantilever structure of the device;
(e) depositing a hydrogen absorbing material on selected areas of the conductive metal layer to form the inner and outer beams of the cantilever structure of the device;
(f) depositing an insulating material on the hydrogen absorbing material of the outer beams of the device; and
(g) etching the oxide layer according to a pattern, thereby forming and releasing the cantilever structure.

15. The method of claim 14, further comprising integrating the MEMS device into a circuit or connecting it to one or more of a battery, a voltage regulator, a wireless sensor node, a processor, a memory, a status indicator or display, a visual or audible alarm, a package housing, a control for regulating the bias voltage, another device, or a load switch for controlling another device.
